(19) United States
(12) Patent Application Publication
(10) Pub. No.: US 2024/0206537 A1
(43) Pub. Date: Jun. 27, 2024

(54) Cartridge Unit for an Electrical Cigarette

(71) Applicant: Carnault AG, Basel (CH)

(72) Inventors: Benjamin Kaiser, Basel (CH); Tobias Kaiser, Basel (CH); Stefan Bauer, Tubingen (DE); Daniel Brock, Chemnity (DE); Michael Schwitzer, Lichtenau (DE)

(21) Appl. No.: 18/041,537

(22) PCT Filed: Aug. 13, 2020
(86) PCT No.: PCT/EP2020/072784

§ 371 Date: Feb. 13, 2023

(30) Foreign Application Priority Data
Jun. 18, 2020 (WO) PCT/EP2020/067041

(51) Int. Cl. A24F 40/42; A24F 40/10; A24F 40/485; A24F 40/51

(52) U.S. Cl. CPC A24F 40/42; A24F 40/10; A24F 40/485; A24F 40/51

(57) ABSTRACT

A cartridge unit for an electrical cigarette is detachable from a control unit. The cartridge unit includes a reservoir housing and a control element body. The reservoir housing has disposed at a bottom thereof a mouthpiece closure having a mouthpiece opening that is fluidically connected to an aerosolization zone and an air duct element. The reservoir housing comprises an aerosol precursor compound supplied by a liquid transport element in the aerosolization zone to a heating element, wherein the heating element receives electrical energy via connecting lines. The reservoir housing has a cartridge closure at an end of the cartridge unit opposite the mouthpiece closure. The control element body is arranged in the cartridge closure, and has a number of electrical contacts to the control unit. The control element body is electrically connected at a bottom thereof to the connecting lines, and forms a snug fit with a body diameter.

### FIELD OF THE INVENTION

The present invention falls within the field of daily life and relates to a cartridge for an electrical cigarette according to the preamble of claim 1.

### BACKGROUND OF THE INVENTION

Conventional electrical cigarettes are hand-held devices which generate an inhalable aerosol using electrical energy from a precursor composition. For this purpose, each electrical cigarette has at least the following functional elements: an energy source, electronic control components, a precursor composition and an aerosolizing unit. The latter can consist of a heating element, for example a glow wire or a heating chip, or another assembly which is capable of transferring the precursor composition into an aerosol, for example with the aid of an ultrasonic atomizer, or by means of a single or two-substance atomizer nozzle. The precursor composition can, on the one hand, consist of a liquid or, on the other hand, contain solid constituents, such as prepared tobacco products (so-called heat-not-burn products).

Electrical cigarettes are designed to be used in the same way as traditional tobacco cigarettes. A use scenario, as is the rule in the consumption of a traditional tobacco cigarette and consequently lies in the range of the expectation for electrical cigarettes, is that the aerosol produced by the electric cigarette is inhaled several times in succession with short pauses between the individual trains. Such a process, wherein the electrical cigarette is usually held in the hand, guided to the mouth and finally the aerosol in the form of a kind of mist or steam is breathed on and in parts again, is also influenced by a desired visibility and perceptibility to external influences. The smoking of traditional tobacco cigarettes was and becomes massive in many parts of the world. In this case, it was sometimes attempted to make it in connection with positive values, such as sociability, authenticity and freedom. The global success of traditional tobacco cigarettes, which is expressed in the high number of consumers of more than one billion people, could be a sign that this experiment is at least partially annealed. Thus, the fact that smoking of tobacco cigarettes is extremely widespread, but not the use of similarly acting, often more favorable and in some cases much less harmful nicotine-containing products, such as, for example, Oral tobacco suggests that the high visibility and perceptibility of the smoking process and of the product has a decisive influence on its success or its ability to be linked to positive values.

These considerations give the conclusion that the success of an electrical cigarette is also highly dependent on the external perception of the product itself and on the outside wasting during use of the product. In the same sense, it is also close to the conclusion that the design for the question is possible, to what extent an electrical cigarette can be credibly connected to just those values which the tobacco cigarette holed to said success. It should be noted that these values already described above are to be referred to at least in that respect as pointers, since they are fundamental, in almost every culture, extensive and intensively subject values in which it can be assumed that they will also be relevant in the future. The product design is thus an essential differentiation feature both with respect to other electrical cigarettes and with respect to traditional tobacco cigarettes and may, under certain circumstances, be the only distinguishing criterion which is visible to the outside. Consequently, it can be advantageous if an electrical cigarette is distinguished by one or more of the following aspects, namely a high-quality material selection of the assemblies which are visible to the outside, a high processing quality, a long service life, possibilities of individualization of the outer design, for example due to an exchangeability of assemblies, a small product size which corresponds to a pleasant hand Haptic and simple handling are encountered, and dimensions which come as close as possible to the shape and size of a classic tobacco cigarette, since it can be assumed that many people are accustomed to the shape and size of classical tobacco cigarettes and, in addition, to their weight. Furthermore, aspects such as environmental friendliness, waste minimization, recycling capability and waste separation of materials is from importance. The same applies with regard to the choice of material. Selected materials, such as wood or elite, are well known to smokers from cigarette-related products such as tobacco whistling, as a result of which the recourse to such materials in electrical cigarettes could also be able to cause familiarity in smokers.

Furthermore, in the electrical cigarette, a control electronics should ensure reliable functioning of the aerosol generation and possibly comprise extended functions, such as, for example, the possibility of a Bluetooth connection to a smartphone or an authentication of the consumable in a so-called cartridge and furthermore the quantity control; in this case, the extended functional scope is associated with an increased space requirement for electronic components or electronic components, for example for more complex circuit structures in and around integrated circuits [IC-integrated circuits]. In addition, such a control electronics comprises a switch-on element in the form of a switch, pushbutton or sensor, which is able to register a flight of the customer (pressure sensor, fuel flow sensor, temperature sensor) and optionally display elements, such as a LED, and components for evaluation. Furthermore, the modularity of electrical cigarettes is advantageous for the purpose of exchanging individual components in the case of further developments and improvements or in the event of damage. For this purpose, various interfaces and contacts are required, which can require an additional space requirement. In the case of a rechargeable battery cell, a high current that can be called up and the highest possible usable capacity are advantageous as an energy source, whereby this is accompanied by the positive correlation between battery capacity and maximum discharge current, as well as the usually unfavourable positive correlation between capacity, maximum discharge current and a correspondingly large volume or mass of such a rechargeable battery cell.

Of course, with a view to low production costs, economic aspects are not ignored, which are based on correspondingly simple assembly, low-cost components or a high degree of automation.

Some of the above-mentioned requirements for electronic cigarettes are in conflict with each other and thus require a trade-off between the advantages that must be met and the secondary disadvantages that go hand in hand with them.

For example, the use of natural materials such as wood or ebonite means that a certain minimum wall thickness cannot be undershot, which is greater than for stainless steel or other metals and alloys, so that, for example, wooden or ebonite tubes require more space. In order to remain as faithful as possible to the shape and size of a tobacco cigarette and, at the same time, to be able to realize a technically advanced electric cigarette, this makes a space-saving design inevitable.

Furthermore, a circular cylindrical housing shape, for example, means that the battery cell must also be circular cylindrical in order to fit optimally into this shape. However, at least for small cell sizes, cuboid battery cells with a higher capacity can be realized for the same volume than circular cylindrical battery cells. This is due to the basic layer structure of battery cells. In a round cell, the electrode and separator layers are usually rolled up, resulting in an unused cavity in the center due to the limited angle of curvature of the layers used. This makes efficient use of installation space in a circular-cylindrical housing all the more important. A cuboid housing design also accommodates the construction of printed circuit boards. A flat and rectangular PCB shape is easier to realize without sacrificing size or functionality, and at the same time can be integrated space-efficiently into a cuboid housing. The electronic components that make up the printed circuit board of a control unit are often rectangular themselves, so they can be arranged more efficiently on a rectangular printed circuit board surface than on a round one. A rectangular housing is therefore more suited to the design of battery cells and PCBs than a circular-cylindrical housing and would, for example, simplify the conflict of goals of small product size, the most powerful battery cell possible and good use of the space on the PCB. As a consequence, however, one moves away from the goal of similarity to the tobacco cigarette.

From the point of view of sustainability and economy, using high-quality materials or investing in a high quality of workmanship only makes sense if the corresponding components have a certain durability. Consequently, it would be disadvantageous if the service life of a battery sleeve, which takes up most of the visible surface area when the electric cigarette is assembled and represents a central design object, were linked to the comparatively limited service life of the battery cell located inside it if both parts were permanently connected to each other. In order to achieve a high quality of workmanship and the use of high-quality materials, especially in the area of the battery sleeve, in a sensible, sustainable and economical manner, a modular, separable structure of the control electronics or control unit, the battery cell and the battery sleeve is a prerequisite. A high degree of modularity here regularly conflicts with a small product size, since the individual parts must have separable mechanical and electrical connections, which generally take up additional space. In addition, as higher demands are placed on the design, it may become more complex: more and/or more complex components may be required, or it may take a greater number of steps to manufacture, which would have a negative impact on final assembly and production costs.

The most powerful battery cells possible conflict with the highest possible functionality of the control electronics and a small product size. Simple assembly of the electric cigarette can conflict with increasingly complex control electronics, which sometimes results in the use of flexible printed circuit boards or various wiring and additional parts for connecting the printed circuit board to the housing, for example injection molded parts etc.

Simple technical operation can also have a negative impact on space requirements and product size, while it is also desirable for the electric cigarette to remain in an assembled and quasi-functional state while the battery is being charged. In this regard, such chargeability may take up additional space as opposed to a permanent closure that does not depict additional functions, for example because additional wiring may be required. Similarly, increased functionality or electrical design requirements may result in increased space requirements. For example, detecting changes in air pressure or air flow during the smoking process so that the electronic cigarette can be used in the same way as a tobacco cigarette necessitates air flow management. This often requires additional components in addition to a pressure sensor.

For example, in U.S. Pat. No. 10,561,178 B2, a conventional electric cigarette comprises a cartridge unit or aerosol dispensing device having a control element body in which a base and a flow regulator define an electronics compartment in which an electronic control component is housed with its electrical connections to a power supply unit located outside the cartridge unit. Publications U.S. Pat. No. 10,292,434 B2 and U.S. Pat. No. 9,955,726 B2 also disclose such an architecture. Common to the disclosed prior art is that the respective cartridge unit disclosed herein comprises an internal volume which, in addition to a substantial volume region for a precursor composition and the aerosolization device, must provide a significant volume region for the electronic control component with its electrical connections.

### Representation of the Invention

It is therefore a task of the present invention to further develop a cartridge unit for an electric cigarette in such a way that the volume available in the cartridge unit is efficiently divided between the volume area for the precursor composition and that volume area for the control component with its electrical connections, i.e. that the control component with its electrical connections is designed to be as efficient as possible with respect to a minimum necessary construction volume and is also designed to be simplified compared to the prior art.

The problem underlying the invention for the cartridge unit of an electric cigarette is solved by the features of claim 1; the features further developing this inventive idea are in each case the subject of subclaims 2 to 15.

Advantageously, the cartridge unit according to the invention for an electric cigarette, which along a central Z-axis from bottom to top comprises said cartridge unit and a control unit detachably arranged thereon, comprises a reservoir housing which towards the bottom has a mouthpiece termination with a mouthpiece opening, wherein the mouthpiece opening is fluidically in operative connection with an aerosolization zone and an air channel element and the reservoir housing contains an aerosol precursor connection which can be supplied to a heating element by means of a liquid transport element in the aerosolization zone, wherein said heating element can be supplied with electrical energy via a first and a second connection line, wherein the reservoir housing has a cartridge closure at an end of the cartridge unit opposite the mouthpiece closure, wherein a control element body is arranged in said cartridge closure, which control element body on the one hand has a number of electrical contacts upwardly towards the control unit and on the other hand is electrically operatively connected downwardly to the first and the second connection line, wherein said control element body forms a snug fit in the cartridge closure with a body diameter perpendicular to the central Z-axis.

The cartridge unit according to the invention is characterized by a consistently efficient use of space of the control element body, which is formed within the cartridge end in such a way that, with the smallest necessary volume, it also has all electrical contacts or all electrical active connections upwards to the control unit of the electric cigarette and downwards to an aerosolization zone; this is achieved by the control element body having such a large body diameter perpendicular to the central Z-axis in the cartridge end that a snug fit is formed therebetween.

In this way, the cartridge unit according to the invention has an improved use of space compared to the prior art and also a higher degree of modularity, because the control element body arranged by means of the fitting seat can be replaced non-destructively if necessary. Such interchangeability becomes more important when the cartridge unit is designed to be refillable several times with an aerosol precursor compound.

An advantageous embodiment provides for the number of electrical contacts to the control unit to be designed as surface contacts or contact surfaces. It would be particularly advantageous to design these surface contacts or contact surfaces as circular or ring surfaces on the end surface of the control element body facing upwards towards the control unit. The number of electrical contacts typically serves to supply power to the cartridge unit and/or to control the cartridge unit by means of the control unit or the control unit by means of the cartridge unit.

Furthermore, it is advantageous if the electrical active connections downwards, i.e. from the control element body to the connecting lines of the heating element, are also designed as surface contacts or as contact surfaces. Without departing from the scope of the present invention, however, it is also conceivable that the electrical active connections in question here are designed as contact pins which interact with the connecting lines of the heating element.

In a further, advantageous embodiment of the cartridge unit, the control element body is formed as a printed circuit board structure. Such a printed circuit board structure may advantageously comprise at least one printed circuit board insulated from the cartridge end by means of an insulation filling, said at least one printed circuit board being oriented transversely to the Z-axis.

In a further embodiment of the cartridge unit, the printed circuit board is equipped with at least one sensor and/or at least one microcontroller and/or at least one further electronic component, which are electrically operatively connected on this printed circuit board by means of a number of conductor tracks or other electrically conductive structures (such as, for example, through-platings, bonding wires, etc.) to the number of electrical contacts, or to the first or the second connecting line, or to an outer surface contact between the control element body and the cartridge closure. In this context, it may also be advantageous if the sensor and/or the microcontroller and/or the electronic component are formed with the printed circuit board as integrated electronic components embedded in the printed circuit board structure. In this way, the highest density of integrable functional elements results in the control element body and thus the most efficient use of space within the cartridge unit. When using multiple PCB planes spaced apart in the Z-direction, additional vias for making further electronic connections are advantageous. Furthermore, the printed circuit board structure advantageously also has an authentication device by means of which the cartridge unit can be identified at the control unit either as released for use or as to be locked.

In a further embodiment of the cartridge unit, it is provided that the control element body for an air flow has a flattening to the cartridge end on its outer circumferential surface; such a flattening can be formed, for example, in the form of a segment of a circle or a section of a circle, with which the air flow within the cartridge unit can be guided past the control element body and in the direction of the control unit. Of course, it would also be conceivable if, instead of the above-mentioned flattening, another variant of a flow channel for the air flow were provided, for example a notch, a groove or a bore.

For the snug fit of the control element body, a snug fit with a so-called clearance fit or a snug fit with a so-called transition fit are particularly suitable, whereby in the former case the control element body is just slightly displaceable in the cartridge unit and in the latter case the control element body is displaceable with slight pressure in the cartridge unit. In both cases shown, it can also be advantageous if the air channel element has an air channel closure towards the control element body, which forms an interference fit with the cartridge closure, whereby the control element body can be fixed in the cartridge closure, but can still be detached if necessary for the purpose of replacement.

In the advantageous embodiment of the control element body with a round cross-section, where the Z-axis of the electric cigarette coincides with the central axis of this control element body, this then appears to be pot-like, button-battery-like or tablet-like, so that this control element body—if it is provided with a circuit board structure—can also be called a circuit board tablet.

Further advantageous embodiments are highlighted with reference to the following figures in connection with the detailed description of the invention.

### BRIEF DESCRIPTION OF THE FIGURES

The invention is explained below by way of example using figures. Identical objects in the figures are generally provided with the same reference signs. At this point it is pointed out that the figures have no limiting effect on the subject matter of the invention, but merely represent possible embodiments of the idea of the invention.

It shows purely schematically the

FIG. 1 a longitudinal sectional view of the electric cigarette according to the invention with a central Z-axis for the purpose of a simple description when locating individual elements of the cigarette by means of the terms, “top”, “bottom”, “towards the top”, “towards the bottom”, “upper end”, “lower end”, “top”, “bottom”, etc., which are also used here in part in the figures;

FIG. 2 another longitudinal sectional view of the electric cigarette according to FIG. 1 with electrical connections;

FIG. 3 an enlarged longitudinal sectional view of the cartridge unit according to FIG. 2;

FIG. 4 a longitudinal sectional view of an embodiment of the cartridge unit according to FIG. 3;

FIG. 5 a longitudinal sectional view of a further embodiment of the cartridge unit according to FIG. 3;

FIGS. 6a, 6b Two exploded views of a cartridge unit reservoir housing;

FIG. 7a, 7b two exploded views of a content of the reservoir housing according to FIG. 6a, 6b;

FIG. 8a, 8b two exploded views of an embodiment of the contents of the reservoir housing according to FIGS. 6a, 6b;

FIG. 9a sectional view of the contents of the reservoir housing shown in FIGS. 6a, 6b with an air flow;

FIG. 10a a perspective side view of the reservoir housing according to FIGS. 6a, 6b with an air flow;

FIG. 10b a perspective longitudinal sectional view of the reservoir housing according to FIGS. 10a, 10b with the air flow, and

FIG. 11 a printed circuit board structure for the cartridge unit according to FIG. 3, FIG. 4 and FIG. 5.

### WAYS TO CARRY OUT THE INVENTION

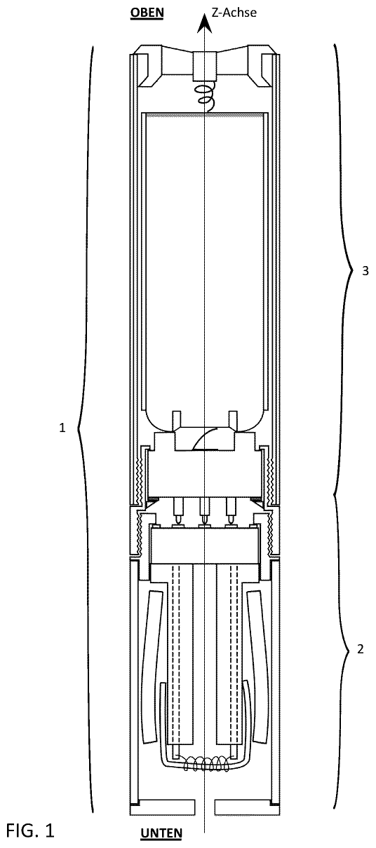

FIG. 1 shows the cartridge unit 2 of an electric cigarette 1 according to the invention with an orientation from the bottom to the top in a Z-direction, wherein this cartridge unit 2 is closed at the top by means of a control unit 3, wherein the cartridge unit 2 and the control unit 3—here exemplarily present—show a mechanical connection in the form of a thread; such a mechanical connection can of course also be designed within the scope of the present invention as a bayonet closure or as a plug-in closure, wherein also latching elements could be considered.

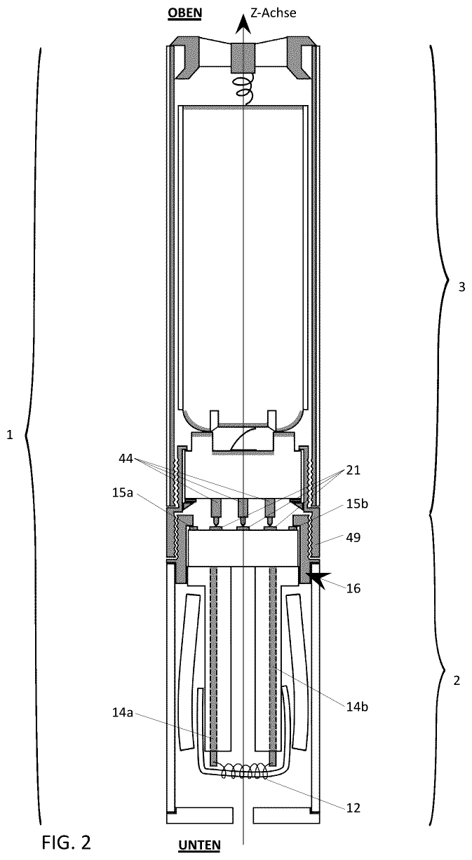

In FIG. 2, moreover, —example—electrical connections between the control unit 3 and the cartridge unit 2 are shown in a highlighted manner: for this purpose, the control unit 3 has a number of pin contacts 44 which interact electrically with a number of contacts 21 of the cartridge unit 2. Furthermore, a closure component 49 of the control unit 3 can form an electrical connection with a cartridge termination 16 of the cartridge unit 2 in the region of its mechanical connection in the form of the thread, this cartridge termination 16 furthermore being electrically connected to a first terminal contact 15a and/or a second terminal contact 15b of the cartridge unit 2. All the electrical connections shown here can serve, on the one hand, for the energy supply of a heating element 12 via their connecting lines 14a, 14b and/or, furthermore, for a comprehensive control of the two interacting units, control unit 3 and cartridge unit 2. Such a control can comprise one or more of the functions listed below, namely an air quantity measurement, a residual quantity determination for the aerosol precursor compound, a charge state determination of an associated energy supply, an authentication device for the purpose of mutual activation and use, a communication device (RFID, Bluetooth, . . . ), if necessary with a smartphone or a smartwatch, a transmission of information on the part of the cartridge unit with regard to the filled aerosol precursor compound for the purpose of tuning the power applied to the cartridge unit, a power adjustment on the basis of the temperature measured in the cartridge unit, a temporary storage of various usage parameters, such as the draw strength, draw duration, draw frequency, in the cartridge unit for the purpose of subsequent readout for product optimization and fault analysis, this list of functions not being to be regarded as complete.

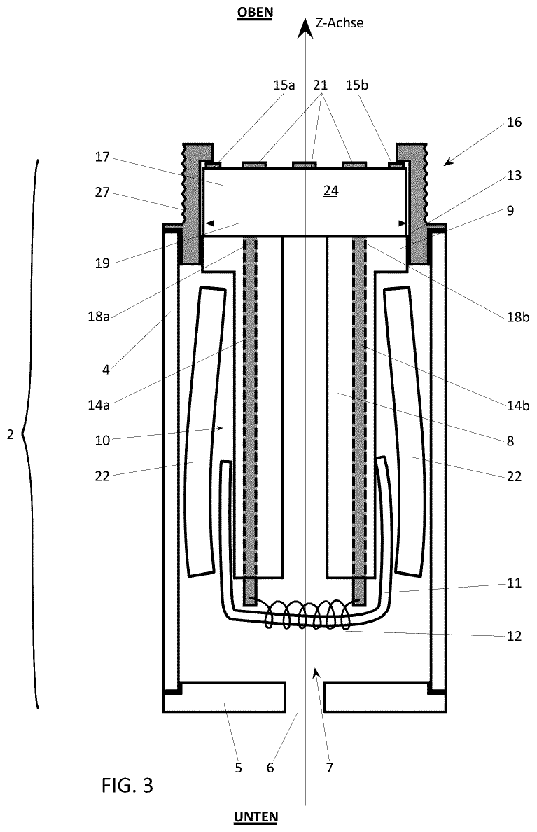

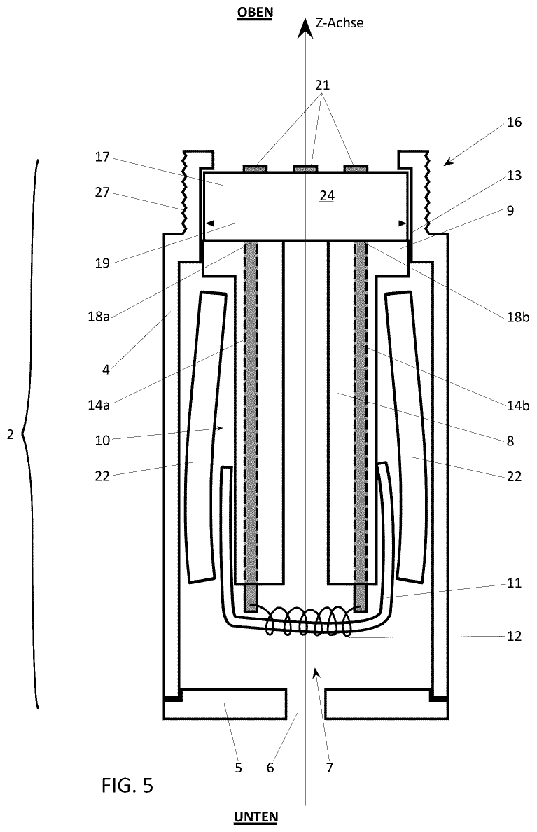

FIG. 3 shows an enlarged longitudinal sectional view of the cartridge unit 2 according to the invention with a reservoir housing 4, which is closed at the bottom by a mouthpiece closure 5 except for a mouthpiece opening 6. At the upper end of the cartridge unit 2, it has a cartridge end 16, which is connected to the reservoir housing 4, as shown here. As will be shown below with reference to FIG. 5, an embodiment of the cartridge unit 2 is also conceivable in which this cartridge unit 2 comprises the reservoir housing 4 and the cartridge closure 16 in one piece. The cartridge closure 16 is closed at the top by a control element body 17 which, according to the invention, has a body diameter 19 which is dimensioned in such a way that the control element body 17 forms a snug fit with the cartridge closure 16; by means of this geometric design, the most efficient possible use is made of the available space volume for the control element body 17 within the cartridge unit 2, whereby its linear expansion in the Z-direction can be limited to a necessary minimum.

Downwardly adjoining the control element body 17 is an air duct closure 9 of an air duct 8, the air duct closure 9 forming an interference fit with a reservoir closure inner wall 13, whereby the control element body 17 can be fixed in the cartridge closure 16. The interference fit between the control element body 17 and the cartridge closure 16 is formed in the present case either as a clearance fit or as a transition fit, whereby in the first case the control element body is arranged so as to be just slightly displaceable and in the second case the control element body is arranged so as to be displaceable with slight pressure, which is why fixation by means of the air duct closure 9 to the reservoir closure inner wall 13 is required. It is noteworthy in this embodiment that all components can be detached from each other non-destructively, if necessary, so that simple disassembly and just as simple assembly is possible if desired—expansion of function- or if required—fault rectification-. In connection with FIG. 2, it can be seen that the cartridge unit 2 is connected to the control unit 3 by means of the thread 27 on the cartridge end 16. As already explained above, another mechanical connection can also be selected here, which can be released non-destructively.

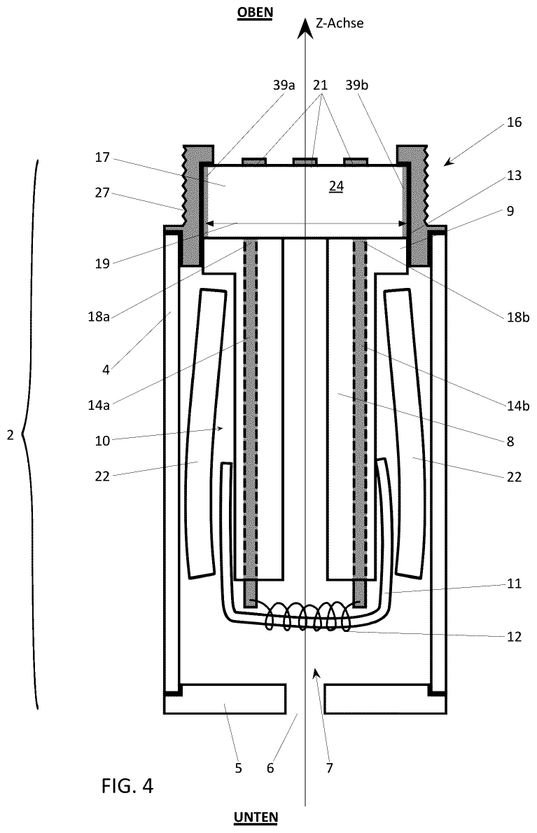

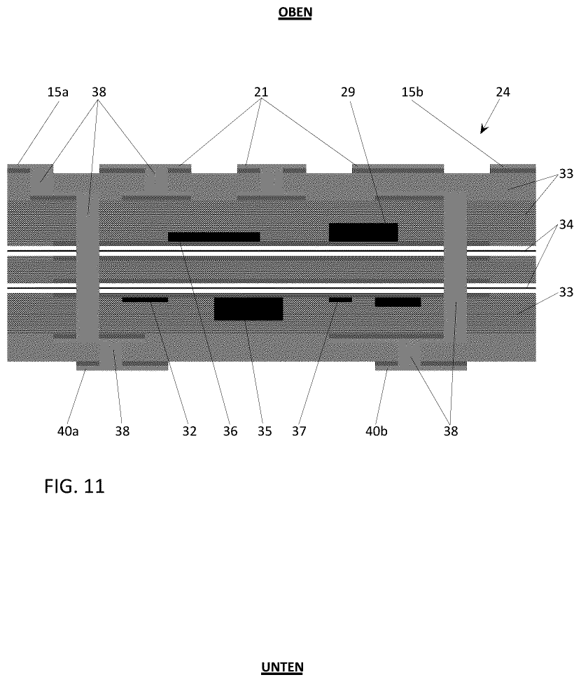

On the one hand, the air channel element 8 serves a centrally guided air flow, which will be described in the following. Furthermore, this air channel element 8 also serves as a carrier for a first and a second connection line 14a, 14b starting from a first and a second line contact 18a, 18b from the control element body 17 to a heating element 12. This heating element 12 is supplied with an aerosol precursor compound 10 by means of a liquid storage substrate 22 and a liquid transport element 11, whereby an aerosol can be provided in an aerosolization zone 7. The first and a second connection line 14a, 14b are in operative connection with the control element body 17, at least in such a way that the power supply to the heating element 12 is effected via this. In one embodiment of the control element body 17, this is formed as a printed circuit board structure 24 (see also FIG. 11) with intelligence. As already mentioned in the above description of FIG. 2, corresponding contacts 15a, 15b, 21 are provided at the upper end of the control element body 17, which on the one hand serve to supply power to the cartridge unit 2 or the circuit board structure 24 and/or on the other hand are used as control contacts. With regard to the electrical contacting of the cartridge unit 2, FIG. 4 shows an embodiment of the invention in which, in contrast to the illustration in FIG. 3, the control element body 17 has a number of lateral surface contacts 39a, 39b which cooperate with the cartridge termination 16 accordingly.

FIG. 5 shows a further embodiment of the cartridge unit 2 according to the invention, in which, in contrast to the illustrations in FIGS. 3 and 4, the cartridge unit 2 is designed in one piece with the cartridge closure 16 and the reservoir housing 4.

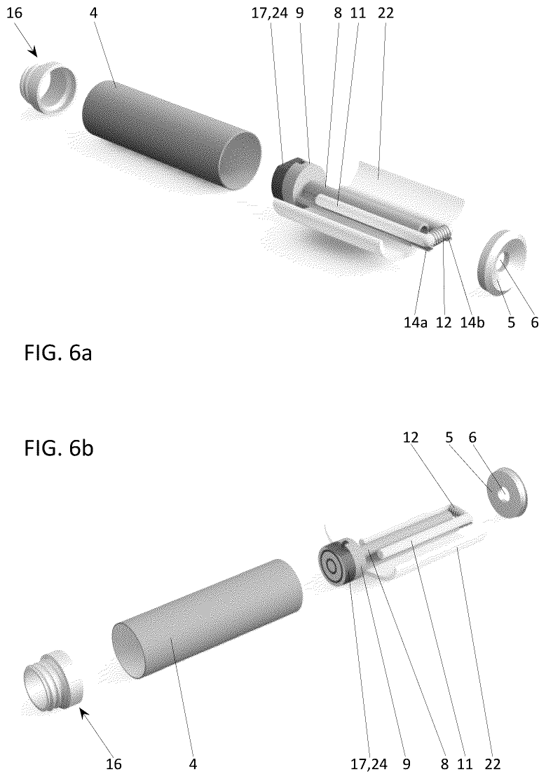

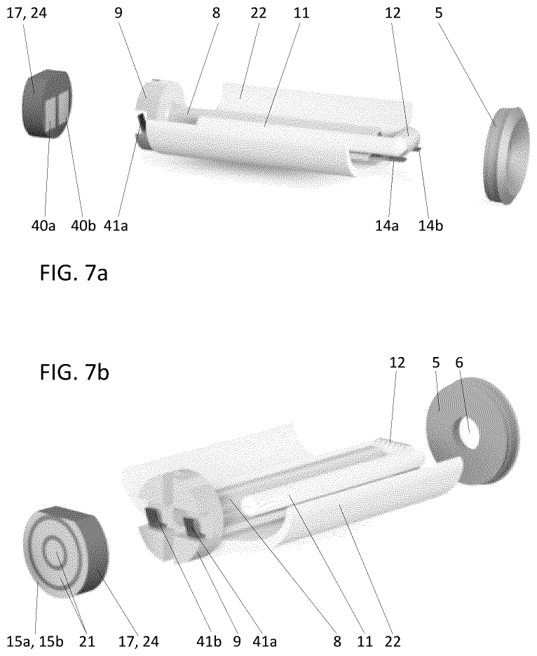

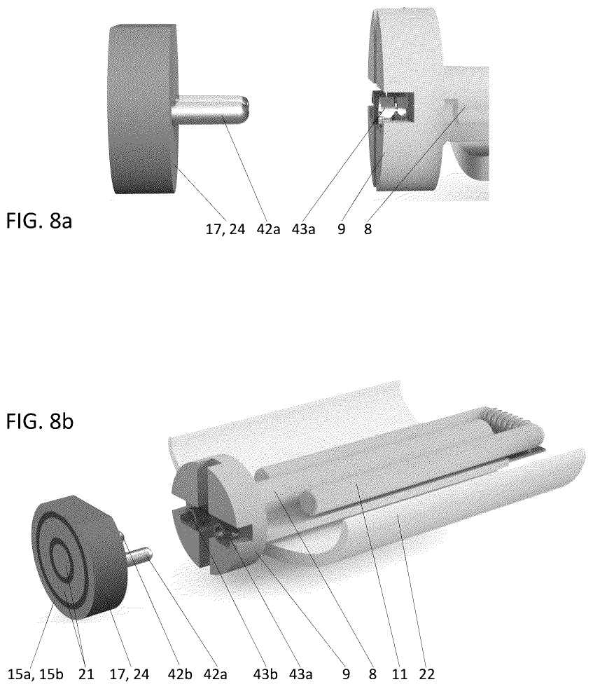

FIGS. 6a, 6b show in a respective exploded view the cartridge unit on the one hand from the mouthpiece end 5 to the cartridge end 16, FIG. 6a, and on the other hand the cartridge unit from the cartridge end 16 to the mouthpiece end 5, FIG. 6b. Here it is clear that the cartridge termination 16 is inserted into the reservoir housing 4 from a first side, while the control element body 17 or the circuit board structure 24 with the air channel element 8, the liquid storage substrate 22 and the internal liquid transport element 11 is inserted into the reservoir housing 4 from a second side, where it is closed with the mouthpiece termination 5. A further detail regarding the electrical connections in the embodiment according to FIGS. 6a, 6b is shown in FIGS. 7a, 7b. Here, too, it is shown in corresponding exploded views that the control element body 17 or the circuit board structure 24 has contact surfaces 40a, 40b facing the air channel element 8, which interact with corresponding spring contacts 41a, 41b of the connecting lines 14a, 14b. FIGS. 8a, 8b show a further embodiment of this electrical connection between the control element body 17 and the circuit board structure 24 shown in FIGS. 7a, 7b, respectively. Here, those contact elements on the control element body 17 and on the circuit board structure 24, respectively, that face the air channel element 8 are formed as contact pins 42a, 42b that correspond to corresponding contact sockets on the air channel element 8 of the connecting lines 14a, 14b.

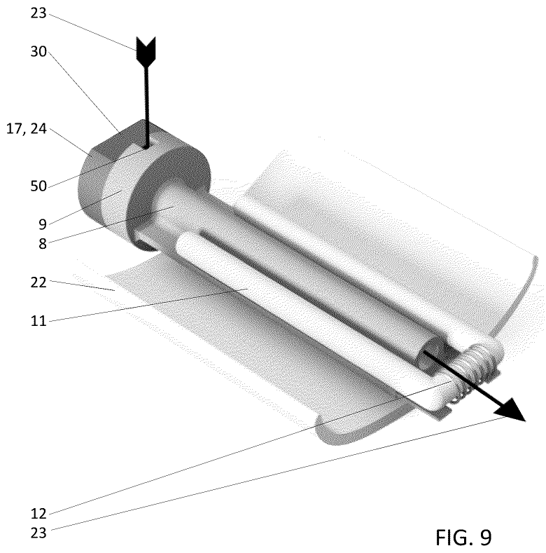

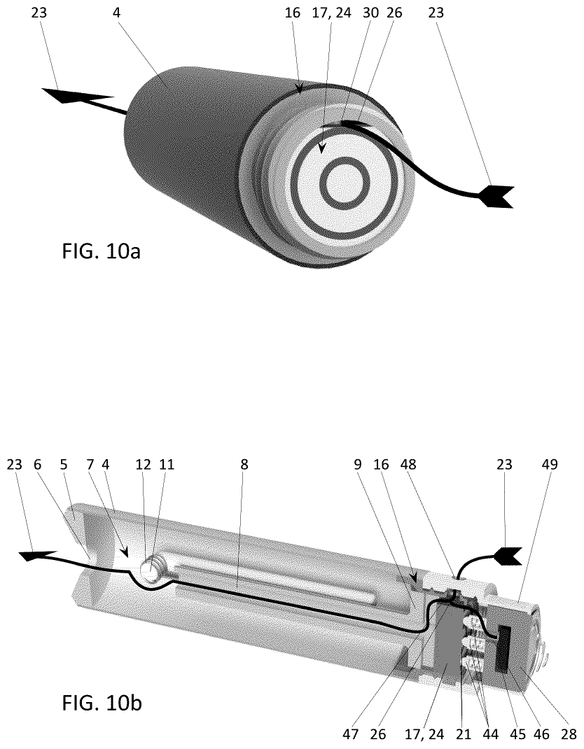

FIG. 9 shows a perspective view of an air flow 23 through the air channel element 8, wherein the air flow 23 is shown as an arrow having an arrowhead and an arrowhead. The air flow 23 enters the air channel element 8 between the control element body 17 and the circuit board structure 24, respectively; for this purpose, this air channel element 8 has an air groove 50 at the air channel end, which air groove 50 corresponds to a lateral flattening 30 of the control element body 17 and the circuit board structure 24, respectively. The perspective view in FIG. 10a illuminates the course of the air flow 23 between the flattening 30 and the cartridge termination 16 into the cartridge unit, and FIG. 10b discloses an example of the flow course of the air flow 23 based on a longitudinal sectional view of the cartridge unit. If the mouthpiece closure 5 is pulled, the air flow 23 enters the cartridge unit through an air inlet 48 of the closure component 49, whereby a negative pressure can be generated to the control unit 28 of the control unit 3 not shown here. This negative pressure causes a switching pulse in the control unit 28 through a communication hole 46 with a pressure sensor 45, which subsequently initiates the switching on of the heating element 12 by the control element body 17 or the circuit board structure 24, and the desired aerosol is provided in the aerosolization zone 7 and directed out of the mouthpiece opening 6 with the air flow 23.

FIG. 11 shows an exemplary embodiment of the printed circuit board structure 24, with the connection contacts 15a, 15b and the contacts 21 at the upper termination of this printed circuit board structure 24 and, terminating at the bottom, the contact surfaces 40a, 40b, which interact with the spring contacts 41a, 41b, not shown here, see also FIGS. 7a, 7b, of the connection lines 14a, 14b. The circuit board structure 24 shown here comprises a number of conductor tracks or vias 38 and a number of integrated structures such as, for example, an authentication unit 29, a switching element 32, a sensor 35, a microcontroller 36 and an electronic component 37, which are arranged on circuit boards 34 formed insulated from one another by means of insulation fillers 33. By means of such a printed circuit board structure 24, a plurality of functions of the electric cigarette can be represented, and, if necessary, further structures can be added or omitted. Without departing from the idea of the invention, it is also conceivable that further functions are formed in the control unit 28 (FIG. 10b), or all functions of the control unit 28 are integrated in the present printed circuit board structure 24.

Presently, FIG. 11 discloses in a greatly enlarged sectional view a possible embodiment for the circuit board structure 24 of the electric cigarette 1. In its simplest form, this circuit board structure 24 comprises at least one circuit board 34 which is equipped with a sensor 35 and/or one or more electrical components 37 and/or a microcontroller 36. An exemplary structure based on embedded electronic components is shown here. In this embedding technology variant shown here, the components 35, 36, 37, which are later placed inside, are soldered by means of a soldering process onto the respective copper layer, which has been structured, for example, by etching, and are covered in the further printed circuit board manufacturing process by cover layers of an insulation filling or of printed circuit board material 33 (prepregs). The copper layers onto which the components are soldered can either be individual foils or, as in the case shown, part of prepared two- or multilayer printed circuit boards consisting of at least one insulator, e.g. of a cured prepreg 33 and two pressed-on copper layers. Depending on the design and the choice of material, the resin in the cover layer materials, for example, is used during the subsequent PCB pressing process to fill voids in the vicinity of the embedded components.

Other embedding technologies are available which also enable the processing of non-housed active electronic components, such as microcontrollers or ASICs, without an extra soldering process. In these technologies, standard processes from the PCB industry, e.g. microdrilling (HDI technology, microvias) and electroplating, are used for component contacting of the later internal electronic components. However, the basic structure with embedded components remains largely the same regardless of the embedded variant selected. Multilayer PCBs with embedded components can also be produced using the 3D printing/additive processes, e.g. on a paste/lacquer basis with drying or curing with UV light.

In addition to embedding electronic components, the use of PCB technology suitable for large-scale production also enables complex 3D structuring of the resulting assembly using standard machining processes while maintaining high accuracy or low tolerances. Mechanical guides and additional external contact elements can be very easily implemented in final PCB processes.

The different layers of the multilayer PCB with embedded electronic components are connected to each other by means of vias 38 (microvias, vias) in a standard PCB process and secure the electrical connections in the Z-axis of the compact assembly.

A control unit designed in this way for the present electric cigarette is distinguished from the prior art not only by improved miniaturization but also by lower energy consumption and lower power dissipation. In the present case, the printed circuit board structure 24 comprises a plurality of printed circuit boards 34 arranged insulated from one another and having embedded elements, such as the microcontroller 36, the sensor 35 and the electrical component 37, which are intended here merely as examples of further embodiments equipped in an equivalent manner; typically, the printed circuit boards 34 arranged here horizontally and thus perpendicularly to the Z axis are spaced apart from insulation fillings 33, with conductor tracks or through-platings 38 partially or completely electrically connecting the printed circuit board structure 24.

### LIST OF REFERENCE SIGNS

1 electrical cigarette
2 cartridge unit
3 control unit
4 reservoir housing
5 mouthpiece closure
6 mouthpiece opening
7 aerosolization zone
8 air channel element
9 air duct closure, flange attachment with connection to 16 (press ring, fit, bayonet lock)
10 aerosol precursor compound
11 liquid transport element
12 heating element
13 Reservoir end inner wall Reservoir end inner wall
14a, 14b first and the second connecting line
15a, 15b electrical contacts
16 cartridge closure
17 control element body
18a, 18b first and a second line contact
19 body diameter
20 holding element
21 Contacts, electrically, towards the control unit
22 liquid storage substrate
23 air flow
24 Circuit board structure with intelligence (authentifier, RFID, flow rate)
25 removed circular segment
26 air passage to the control unit
27 connection structure to control unit, thread, bayonete
28 controller
29 authentication unit
30 Flattening, removed segment or section of circle
31 outer shell surface
32 switching element
33 insulation filling
34 printed circuit board
35 sensor
36 microcontroller
37 electronic component
38 through-hole plating
39a, 39b shell surface contact
40a, 40b contact surfaces
41a, 41b spring contacts
42a, 42b contact pin
43a, 43b contact socket
44 pin contact
45 pressure sensor
46 communication hole
47 thread recess
48 air inlet
49 locking component
50 air groove

1.-15. (canceled)

16. A cartridge unit for an electrical cigarette having, along a central Z-axis from bottom to top, said cartridge unit and a control unit detachably arranged thereon, said cartridge unit comprising:
a reservoir housing, having disposed at a bottom thereof a mouthpiece closure having a mouthpiece opening, wherein the mouthpiece opening is fluidically connected to an aerosolization zone and an air duct element, the reservoir housing comprising an aerosol precursor compound which can be supplied by a liquid transport element in the aerosolization zone to a heating element, wherein said heating element can be supplied with electrical energy via first and second connecting lines, wherein the reservoir housing has a cartridge closure at an end of the cartridge unit opposite the mouthpiece closure;
a control element body arranged in the cartridge closure, the control element body having a number of electrical contacts to the control unit, the control element body electrically connected a bottom thereof to the first and the second connecting lines, wherein the control element body forms a snug fit with a body diameter perpendicular to the central Z-axis in the cartridge closure.

17. The cartridge unit according to claim 16, wherein the electrical contacts to the control unit are formed as surface contacts or contact surfaces.

18. The cartridge unit according to claim 16, wherein the electrical operative connection to the first and the second connecting line comprise surface contacts, contact surfaces, or contact pins.

19. The cartridge unit according to claim 16, wherein the control element body comprises a printed circuit board structure.

20. The cartridge unit according to claim 19, wherein the printed circuit board structure comprises at least one printed circuit board insulated from the cartridge closure at least in part by an insulation filling, and wherein said at least one printed circuit board is oriented transversely to the Z-axis.

21. The cartridge unit according to claim 20, wherein the at least one printed circuit board has at least one electronic component which is electrically connected on the at least one printed circuit board by means of a conductor track and/or by means of a via to at least one of the electrical contacts, or to the first or second connecting lines, or to a lateral surface contact between the control element body and the cartridge closure in an electrical operative connection.

22. The cartridge unit according to claim 21, wherein the at least one electronic component comprises a sensor.

23. The cartridge unit according to claim 21, wherein the at least one electronic component comprises a microcontroller.

24. The cartridge unit according to claim 21, wherein the at least one electronic component is configured as an integrated electronic component embedded in the circuit board structure.

25. The cartridge unit according to claim 21, wherein the printed circuit board structure comprises an authentication device.

26. The cartridge unit according to claim 19, wherein the printed circuit board structure comprises an authentication device.

27. The cartridge unit according to claim 19, wherein the printed circuit board structure comprises a switching element.

28. The cartridge unit according to claim 16, wherein the control element body has a flattening with respect to the cartridge closure configured to provide an air flow on an outer lateral surface.

29. The cartridge unit according to claim 28, wherein the flattening on the control element body is in operative fluid communication with the air duct element.

30. The cartridge unit according to claim 29, wherein n that the flattening on the control element body is in operative fluid communication with the control unit of the electrical cigarette.

31. The cartridge unit according to claim 16, wherein the control element body includes a fitting seat formed in the cartridge closure configured as a clearance fit, wherein the control element body is configured to be slightly displaceable.

32. The cartridge unit according to claim 16, wherein the control element body includes a a fitting seat formed in the cartridge closure configured as a transition fit, wherein the control element body is configured to be displaceable responsive to low pressure.

33. The cartridge unit according to claim 16, wherein the air duct element has, proximate to the control element body, an air duct closure which is connected to the cartridge closure by a press fit, whereby the control element body can be fixed in the cartridge closure.
